(19) United States
(12) Patent Application Publication
(10) Pub. No.: US 2014/0166991 A1
(43) Pub. Date: Jun. 19, 2014

(54) TRANSPARENT LIGHT-EMITTING DISPLAY

(71) Applicants: Dmitri E. Nikonov, Bearverton, OR (US); Vivek K. Singh, Portland, OR (US)

(72) Inventors: Dmitri E. Nikonov, Bearverton, OR (US); Vivek K. Singh, Portland, OR (US)

(21) Appl. No.: 13/716,644

(22) Filed: Dec. 17, 2012

(51) Int. Cl. H01L 27/32; H01L 51/56

(52) U.S. Cl. CPC H01L 27/3276; H01L 51/56
USPC 257/40; 438/23

(57) ABSTRACT

A transparent light emitting display is described. A display has a transparent substrate, a plurality of light emitting elements on the substrate, and transparent wires on the substrate to provide an electrical connection to each light emitting element.

### FIELD

The present description is related to display technology and, in particular, to a display that appears to be transparent.

### BACKGROUND

Graphics displays are traditionally viewable only on one side and are opaque. A liquid crystal display includes substantial circuitry on a glass substrate and is backed by a backlight to project light through the liquid crystal structure. The backlight structure sends light in one direction through the liquid crystal structure and the liquid crystal structure only allows light to pass through the crystal structures and not the electronic and electrical components that are connected to the crystal structures. Similarly a plasma display is one sided. One side presents the glowing phosphors while the other side contains the electronic and electrical components used to drive the phosphors.

In order to provide a more transparent display, projectors have been used to project light from a distance onto a semi-transparent display screen. This approach is limited in that the projection screen must capture the projected light but pass all other light. Since both functions are performed imperfectly, the display is typically dim and the screen is only partially transparent.

### BRIEF DESCRIPTION OF THE DRAWING FIGURES

Embodiments of the invention are illustrated by way of example, and not by way of limitation, in the figures of the accompanying drawings in which like reference numerals refer to similar elements.

FIG. 1 is a diagram of a user viewing transparent display as seen from the side of the display opposite the user according to an embodiment of the invention.

FIG. 2A is a diagram of a transparent display according to an embodiment of the invention.

FIG. 2B is a diagram of a computer system with a transparent display according to an embodiment of the invention.

FIG. 3A is a diagram of a transparent display showing annotations superimposed over a view through the display according to an embodiment of the invention.

FIG. 3B is a diagram of a compact personal computing or telephone system with a transparent display according to an embodiment of the invention.

FIG. 4 is a diagram of a cross-section of a transparent display according to an embodiment of the invention.

FIG. 5 is a diagram of a cross-section of an emissive element of a transparent display according to an embodiment of the invention.

FIG. 6 is a block diagram of a computing device containing dies with off-plane conductive lines according to an embodiment of the invention.

### DETAILED DESCRIPTION

A transparent display screen may be used to allow a display to be viewed from either side of the display panel. This allows the display to be more easily shared. It may also be used to allow a viewer of the display to see through the display to what is on the other side. This allows for greater situational awareness for the user. Greater situational awareness may be useful if the user is moving or if the user is interacting with objects or persons on the other side of the display.

With the advent of very bright and small light emitters, such as light emitting diodes (LED), including organic LEDs (OLED), a display can be constructed that has a distance between each light emitter. If the light emitters are mounted to a transparent substrate, such as a plastic screen, then a viewer may be able to see between the light emitters to see what is on the other side of the display. The plastic and connecting wires may also be made of a flexible material so that the display is flexible.

In the described examples, electrodes are attached to every pixel. Peripheral circuits, including drivers for the columns and rows of pixels are positioned on the sides of the display. The electrodes are made of transparent materials, such as indium tin oxide (ITO) or graphene The electrodes, in the case of an OLED serve as the anode and cathode of each OLED. The conductive layer of the OLED can be made, for example, of e.g. PEDOT:PSS aka Poly(3,4-thylenedioxythiophene) poly(styrenesulfonate), while the light emitting layer can be made, for example, of e.g. of poly(p-phenylene vinylene) or polyfluorene.

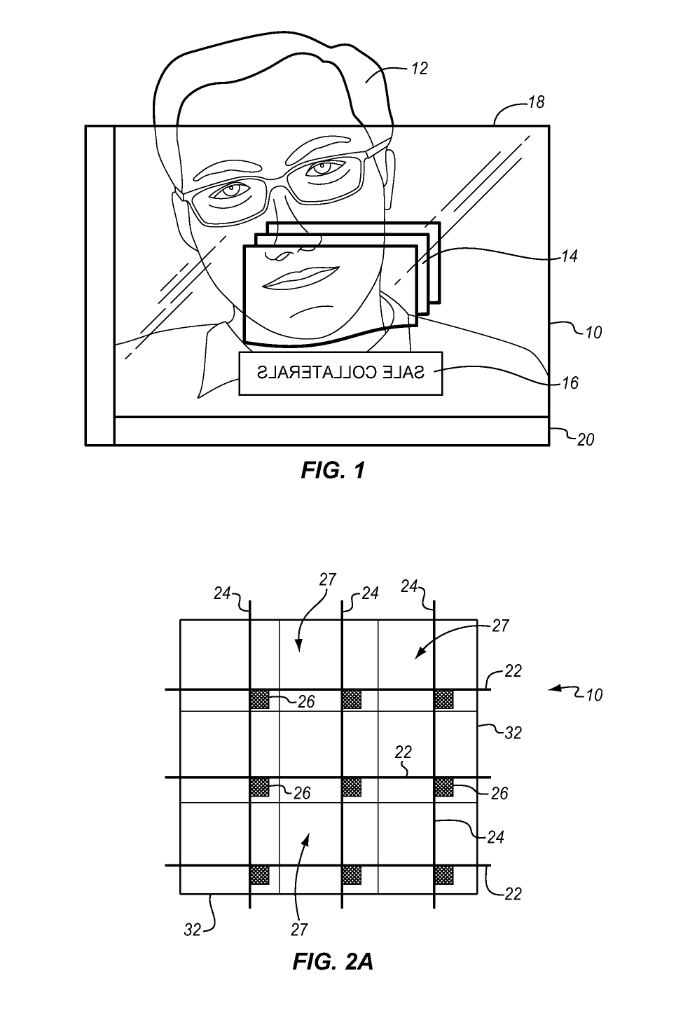

FIG. 1 is diagram of an example of a transparent display 10 which is being viewed by a viewer or user 12. The display shows a set of cascaded windows 14 and some menus 16. The display 10 has a transparent substrate 18 so that a person on the near side of the display can see through the display to the viewer 12 on the opposite or far side. The displayed menus and windows are generated by electronics 20 that surround the display. In this configuration the viewer 12 can share the display with a person on the opposite side and a conversation or interaction about the display can be had from both sides of the display 10 at the same time.

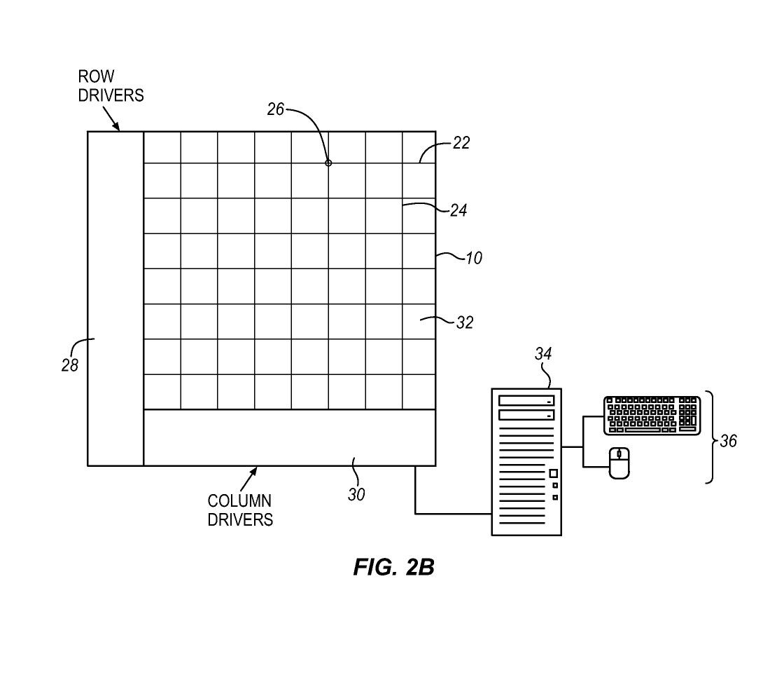

FIG. 2A is a side elevation diagram that shows the connections and structure of the display 10 more clearly. The display 10 has a matrix of row 22 and column 24 wire lines that connect at each junction to a light emitting element 26. The wires and light emitting elements are formed on a display substrate 32 that can be formed of a plastic screen and the light emitting elements may be OLEDS. The transparent substrate 32 may be formed of glass or plastic or any other desired transparent material. If the substrate is composed of a transparent plastic it may also be made flexible so that its shape may be curved or changed depending on the application. The light emitters are shown as all being identical black squares, however, they may be different in size, shape, and configuration. They may all be white or some other color or they may be different colors arranged in an appropriate pattern for the intended use. For a color display, for example, an RGB, YUV, or other pattern may be used.

FIG. 2B is a diagram that shows display of FIG. 2A with the connections and additional structure to interface with a computing system. As in FIG. 2A, the display 10 has a matrix of row 22 and column 24 wires and a light emitting element 26 at each junction. The rows and columns are driven by row drivers 28 and column drivers 30. The display substrate 32 supports the row and column wires and the emitting elements. It may also support the drivers 28, 30, so that the entire structure is built upon a single substrate.

Electrodes are attached at each pixel 26 and the peripheral circuits such as drivers 28 and 30 are positioned on the edge of the substrate 10. In the example of FIGS. 2A and 2B, the display is rectangular with four sides. Adjacent to two of the sides, row drivers and column drivers are attached at the display. The wires 22 24 for rows and columns may also may be made of transparent materials such as indium tin oxide (ITO) or graphene. Additional components may also be located with the row and column drivers. In one embodiment, the row and column drivers are formed on the same transparent substrate as the display. In another embodiment, connectors or traces are formed on the transparent substrate. The row and column drivers are formed on a different substrate which is physically attached to the transparent substrate and electrically connected through the connectors or traces.

In the example of FIG. 2B the display 10 is coupled to a computing device 34 that provides signals to the row and column drivers using stored information and central processing and graphics processing elements present in the computer 34. The computer may also have a user interface 36 such as a mouse and keyboard or a touch pad or any other type of user controller or input device.

In the example of FIGS. 2A and 2B, the viewable part of the transparent substrate contains only row and column wires 22, 24 and light emitters 26. Each light emitter such as an OLED may be contained in a small space for example a ten micron by ten micron area on the substrate. Due to the intensity of the light emitted by the OLED, the emitters may be spaced at a distance from each other that is greater than their size, for example 100 microns. This means that in a display with many 10 micron light emitters all spaced 100 microns from each other almost 90 percent of the display area will be transparent. This is shown in FIG. 2A with 100 micron square pixels 27 each having a 10 micron square OLED 26. The relative amount of transparent area can easily be seen in this diagram. While the pixels and OLEDs are shown as square, this is not necessary to achieve the described transparency. The OLED is shown as a simple square, however, it may have a different shape and configuration. It is further not necessary that the OLED be placed in a corner or any other particular location within each pixel.

In order in ensure greater transparency, the wires connecting the row and column drivers 28, 32 to each light emitter 26 may also be made transparent. While a typical wire is very thin and will not be easily seen from a distance, there are many wires in the display. As a result, the display will appear to be more transparent if the wires are made from a conductive transparent material. A conventional computer monitor has a distance of about 300 microns between pixels so a 100 micron spacing will provide a very pixel dense display. The distance between the pixels may be made greater or smaller depending on the intended use and performance of the display. The display 10 of FIGS. 1 and 2 may be in the form of a conventional computer desktop monitor or it may be much larger or smaller for fixed standing installations or for small portable applications.

The transparent display may be formed in any of a variety of different ways. The substrate may be plastic, glass, various crystal structures or another transparent material. The light emitters, such as OLEDs are then formed on the substrate and the wires are formed on the substrate to connect with the OLEDs. OLEDs may be formed in a manner similar to liquid crystals or by printing. The wires may be formed by first depositing a layer of material, such as indium tin oxide or graphene, by chemical vapor deposition, and then etching away, such as by plasma etching, all but the lines that will be used for wires. Wires may also be formed by printing and heating, among other ways. Connectors are formed on the edges of the substrate to connect the wires to other devices. If drivers or other circuitry are also formed on the edges of the display as shown for example in FIG. 2B, then the drivers and connectors may be formed using conventional silicon processing technologies, such as silicon semiconductor photolithography.

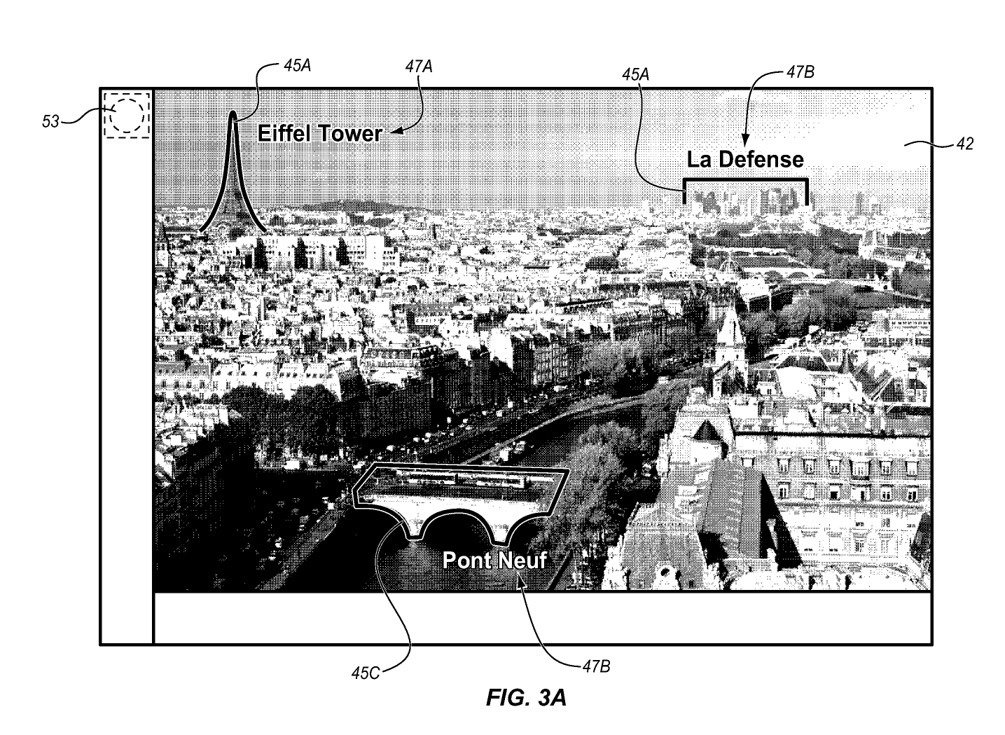

FIG. 3A shows an alternative application for a transparent display in this case as a hand held tablet, slate, personal information manager, gaming device or controller, or smart phone. The device 40 has a transparent display 42 with a grid of row and column wires 44 that couple to light emitting elements at each row and column junction 48. These light emitting elements are driven by row and column drivers 50 which are on the edges of the display. The row and column drivers therefore do not obscure viewing through the display and between the light emitting elements 48.

The display is driven by a central processing unit 52 that has access to a memory 54 for storing instructions and data. The CPU may contain or be coupled to central processing, graphics processing, and communications elements and is coupled also to a user input system 56. The CPU and memory may be part of an integrated system on a chip SOC or provided as separate dies, modules, or packages. The user input system may include buttons, keys, direction controllers, alpha numeric keys, touch surfaces or any of a number of other input systems. If the device 40 is portable it may also be powered by a battery 58. If the device is hand held, a user may be able to hold the device in his hand while looking at the display and still be able to see what is in front of him or below him on the ground. The transparent display in a portable device provides a wide range of different uses. As an example the user may be able to view the display while also viewing distant or nearby objects. This is shown, for example in FIG. 3B.

In FIG. 3B, the display 42 of the handheld device of FIG. 3A or any other device with a transparent display is positioned so that a view of a cityscape is in view through the display. The view may be of any city, building, landscape, starscape, decorative item, animal or other view. The system 40 presents explanatory indications on the display. In the illustrated example, the view is along the river in Paris. The display presents an outline 45A around the Eiffel Tower and identifies with accompanying text 47A. Similarly La Defense 45B and Pont Neuf 45C are also circled and identified with text 47B, 47C. The particular items to identify may be managed using search terms or user preferences among others. The particular items to identify may also be related to input from other applications or gaming interactions. Similarly, the particular nature of identifying and marking items may be adapted to suit different purposes. Codes, symbols, arrows, colors, and other features may be used to tag or mark features in the view.

The scene is viewed by a camera 53 mounted to the display housing or located nearby with a similar view. The processor 52 can receive the camera view and apply image recognition software to recognize the scene and to find landmarks or other information to mark. The camera view may also be sent to external processing or data resources to obtain information. The identified objects may be cross-referenced with any one or more of a variety of internet databases, such as online encyclopedias, locality info, and even personal records of the device user.

The processor generates the outlines 45 and provides the context information 47. The information may include what or who it is and its salient characteristics The resulting data may be identifications 47, as shown, or any other type of information, including travel routes, time tables, bus routes, connecting points, or known locations of individuals or movable items. Warehouse inventory and location as well as machinery repair information can also be provided. The display may be used for example to identify the location of nuts in a remove and replace operation. As shown in FIG. 3A, the outlines or other pointers and the context information are displayed and overlaid on the view through the transparent display 42.

Any of a variety of different augmented reality techniques may be applied to further enhance the image. The camera view may also be used to align the outlines and text generated by the CPU with the corresponding items in view through the transparent display. As the user moves the display, the view through the display will change and the displayed identifications may be moved to follow the view. In addition, identifications can be added and deleted as different items come into and out of view.

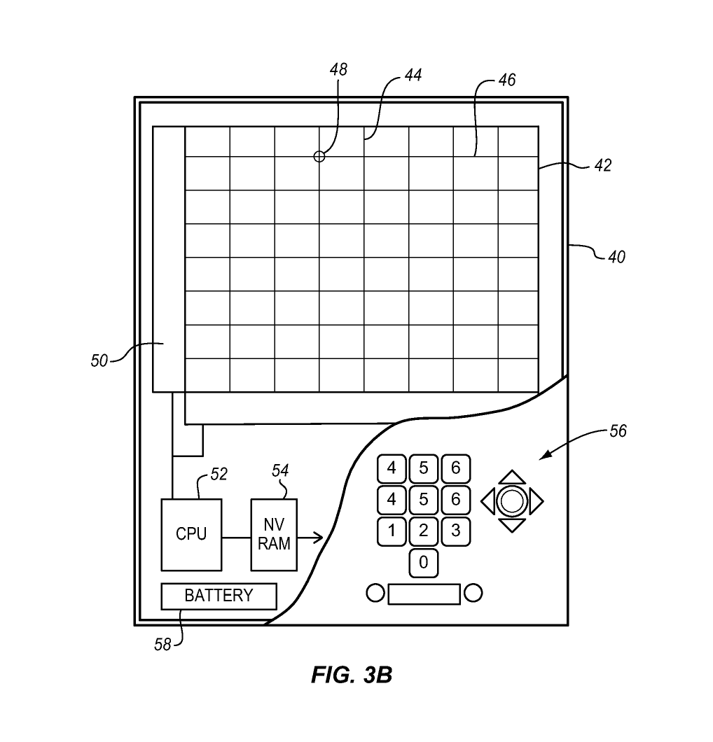

FIG. 4 is a cross-sectional view of a portion of the display substrate to show an example of a transparent display as described above in more detail. The display is mounted to a transparent substrate 62. A layer of transparent wires 64 are attached to the substrate. These wires connect to light emitting devices such as OLEDS 66. A further layer of transparent wire 68 may also be provided for the OLED and a protective coating 70 is applied over the wires and light emitters to protect them. The coding may be an electo-deposited or chemical vapor deposited coating or it may be an additional transparent substrate such as glass or plastic similar to that of the back substrate 62.

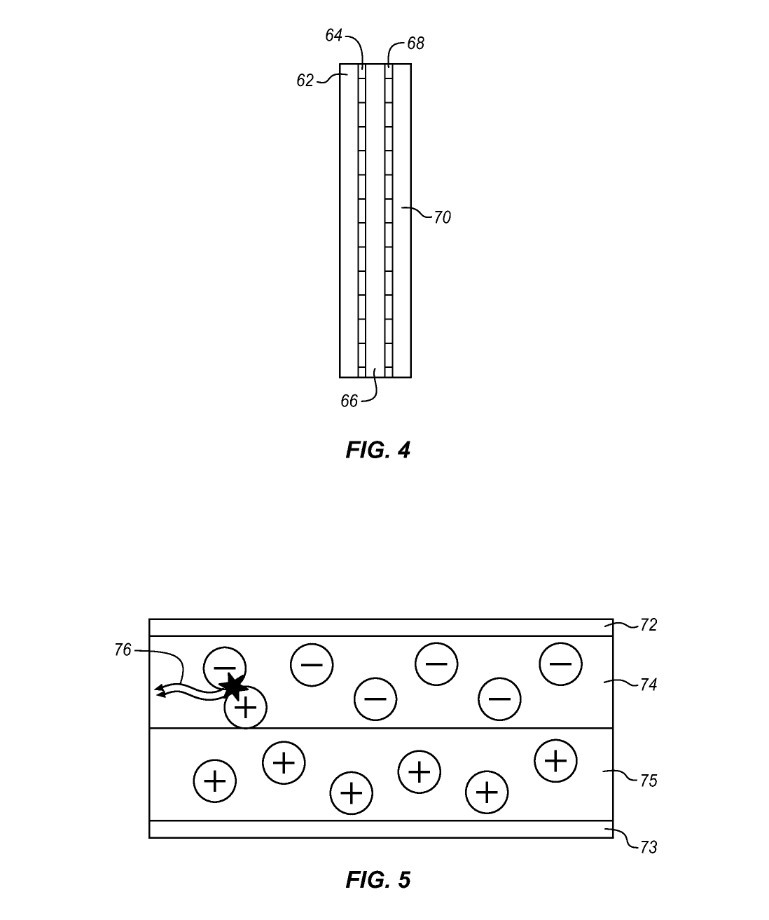

FIG. 5 is a more detailed cross-sectional view of the light emitter structure of FIG. 4 in the form of an OLED. In this cross section view similar to the cross section of FIG. 4 the cathode 72 is on one side and an anode 73 is on the opposite side. The cathode and anode may correspond to the electrodes 64, 68 of FIG. 4. The OLED contains an emissive layer 74, shown here with negatively charged elements, and a conductive layer 75, shown with positively charged elements. When excited, the positive and negative elements interact and the light emitter emits light 76 which may be passed through the electrodes 72, 73 and through the transparent substrates and coatings 62, 70 of the display.

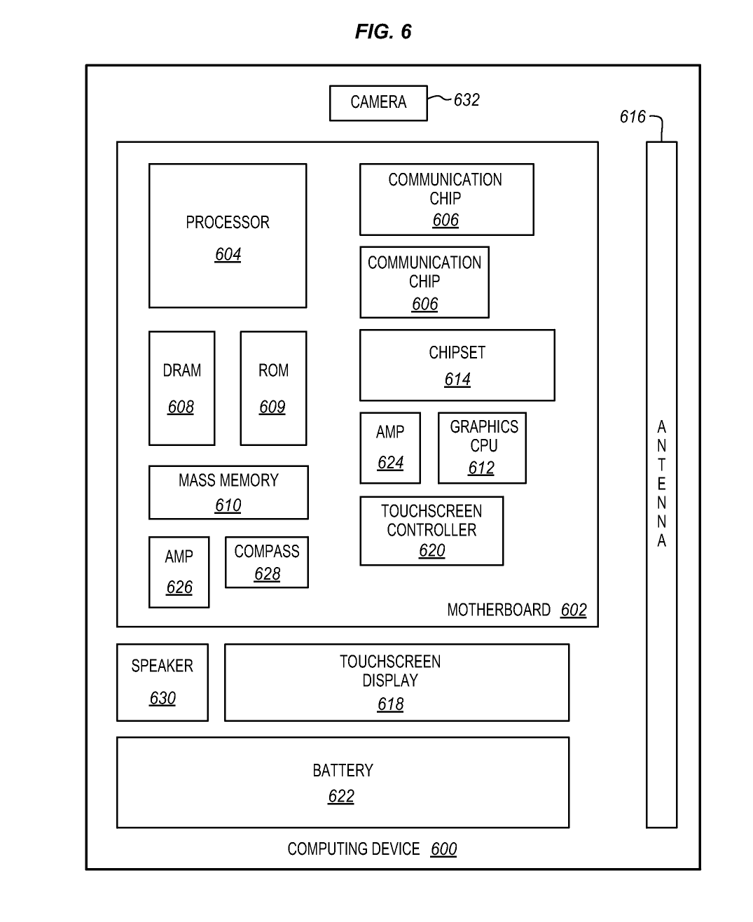

FIG. 6 is a block diagram of a computing device 900 in accordance with one implementation of the invention. The computing device includes a display 918 which may be constructed as a transparent display as described above. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

Depending on its applications, computing device 900 may include other components that may or may not be physically and electrically coupled to the board 902. These other components include, but are not limited to, volatile memory (e.g., DRAM) 908, non-volatile memory (e.g., ROM) 909, flash memory (not shown), a graphics processor 912, a digital signal processor (not shown), a crypto processor (not shown), a chipset 914, an antenna 916, a display 918 such as a touchscreen display, a touchscreen controller 920, a battery 922, an audio codec (not shown), a video codec (not shown), a power amplifier 924, a global positioning system (GPS) device 926, a compass 928, an accelerometer (not shown), a gyroscope (not shown), a speaker 930, a camera 932, and a mass storage device (such as hard disk drive) 910, compact disk (CD) (not shown), digital versatile disk (DVD) (not shown), and so forth). These components may be connected to the system board 902, mounted to the system board, or combined with any of the other components.

The communication chip 906 enables wireless and/or wired communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the invention, the integrated circuit die of the processor, memory devices, communication devices, or other components include one or more dies that are formed with off-plane conductive line interconnects in accordance with implementations of the invention. The term “processor” may refer to any device or portion of a device that processes electronic data from registers and/or memory to transform that electronic data into other electronic data that may be stored in registers and/or memory.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The following examples pertain to further embodiments. Specifics in the examples may be used anywhere in one or more embodiments. In one embodiment, an apparatus comprises a display having a transparent substrate, a plurality of light emitting elements on the substrate, and transparent wires on the substrate to provide an electrical connection to each light emitting element.

Further embodiments include the above apparatus wherein the transparent substrate has an edge, the display further comprising a connection array on the edge of the substrate, and wherein the transparent wires on the substrate connect each light emitting element to the connection array.

Further embodiments include the above apparatus further comprising driver circuits on the edge of the substrate for each light emitting element wherein the connection array is coupled to driver circuits. Further embodiments include the above apparatus wherein the transparent substrate is formed of flexible plastic, wherein the light emitting elements are formed of organic light emitting diodes, and, wherein each light emitting element is spaced apart from each other light emitting element by a distance greater than its width, such as ten times greater than its width.

Further embodiments include the above apparatus wherein the transparent wires are formed of indium tin oxide, and wherein the transparent wires are formed of graphene and wherein the substrate is rectangular having four sides and wherein the connection array is on two adjacent sides of the four sides, the connection array on the first side addressing rows of the light emitting elements and the connection array on the second side addressing columns of the light emitting elements. Further embodiments have a transparent protective layer on the substrate and covering the transparent wires.

In one embodiment, a computer comprises a transparent display on a transparent substrate, a plurality of light emitting elements on the substrate, transparent wires on the substrate to provide electrical connections to each light emitting element, a central processing unit coupled to the display, and memory coupled to the central processing unit to store instructions and data.

Further embodiments include the above apparatus including a user input connector coupled to the central processing unit to receive an input from an external user input device. In further embodiments the transparent substrate has an edge, the display further comprising a connection array on the edge of the substrate coupled to the central processing unit, and transparent wires on the substrate to connect each light emitting element to the connection array.

In another embodiment, a method comprises forming a plurality of light emitting elements on a transparent substrate, and forming transparent wires on the substrate to provide an electrical connection to each light emitting element. In further embodiments, the transparent substrate has an edge, the method further comprising forming a connection array on the edge of the substrate coupled to the transparent wires on the substrate, and the transparent substrate is formed of flexible plastic. Further embodiments include forming a transparent protective layer on the substrate and covering the transparent wires. In further embodiments forming the transparent wires comprises forming wires by chemical vapor deposition. Further embodiments include forming driver circuits on edges of the transparent substrate using silicon semiconductor photolithography.

What is claimed is:

1. A display comprising:
a transparent substrate;
a plurality of light emitting elements on the substrate; and
transparent wires on the substrate to provide an electrical connection to each light emitting element.

2. The display of claim 1, wherein the transparent substrate has an edge, the display further comprising a connection array on the edge of the substrate, and wherein the transparent wires on the substrate connect each light emitting element to the connection array.

3. The display of claim 2, further comprising driver circuits on the edge of the substrate for each light emitting element wherein the connection array is coupled to driver circuits.

4. The display of claim 1, wherein the transparent substrate is formed of flexible plastic.

5. The display of claim 1, wherein the light emitting elements are formed of organic light emitting diodes.

6. The display of claim 1, wherein each light emitting element is spaced apart from each other light emitting element by a distance greater than its width.

7. The display of claim 5, wherein the distance is ten times greater than its width.

8. The display of claim 1, wherein the transparent wires are formed of indium tin oxide.

9. The display of claim 1, wherein the transparent wires are formed of graphene.

10. The display of claim 2, wherein the substrate is rectangular having four sides and wherein the connection array is on two adjacent sides of the four sides, the connection array on the first side addressing rows of the light emitting elements and the connection array on the second side addressing columns of the light emitting elements.

11. The display of claim 1, further comprising a transparent protective layer on the substrate and covering the transparent wires.

12. A computer comprising:
a transparent display on a transparent substrate;
a plurality of light emitting elements on the substrate;
transparent wires on the substrate to provide electrical connections to each light emitting element;
a central processing unit coupled to the display; and
memory coupled to the central processing unit to store instructions and data.

13. The computer of claim 12, further comprising a user input connector coupled to the central processing unit to receive an input from an external user input device.

14. The computer of claim 12 wherein the transparent substrate has an edge, the display further comprising a connection array on the edge of the substrate coupled to the central processing unit, and transparent wires on the substrate to connect each light emitting element to the connection array.

15. A method comprising:
forming a plurality of light emitting elements on a transparent substrate;
forming transparent wires on the substrate to provide an electrical connection to each light emitting element.

16. The method of claim 15, wherein the transparent substrate has an edge, the method further comprising forming a connection array on the edge of the substrate coupled to the transparent wires on the substrate.

17. The method of claim 15, wherein the transparent substrate is formed of flexible plastic.

18. The method of claim 15, further comprising forming a transparent protective layer on the substrate and covering the transparent wires.

19. The method of claim 15, wherein forming the transparent wires comprises forming wires by chemical vapor deposition.

20. The method of claim 15, further comprising forming driver circuits on edges of the transparent substrate using silicon semiconductor photolithography.
